(19) United States
(12) Patent Application Publication
(10) Pub. No.: US 2015/0075419 A1
(43) Pub. Date: Mar. 19, 2015

(54) METHOD FOR PRODUCING SiC SINGLE CRYSTAL

(71) Applicants: Toyota Jidosha Kabushiki Kaisha, Toyota-shi Aichi-ken (JP); Nippon Steel & Sumitomo Metal Corporation, Chiyoda-ku Tokyo (JP)

(72) Inventors: Motohisa Kado, Toyota-shi Aichi-ken (JP); Hironori Daikoku, Toyota-shi Aichi-ken (JP); Kazuhiko Kusunoki, Chiyoda-ku Tokyo (JP); Kazuhito Kamei, Chiyoda-ku Tokyo (JP)

(21) Appl. No.: 14/483,651

(22) Filed: Sep. 11, 2014

(30) Foreign Application Priority Data
Sep. 13, 2013 (JP) 2013-191186

(51) Int. Cl. C30B 19/10; C30B 29/36; C30B 19/06; C30B 19/04; C30B 19/12

(52) U.S. Cl. CPC C30B 19/10; C30B 19/04; C30B 19/12; C30B 19/062; C30B 29/36
USPC 117/60

(57) ABSTRACT

A method for producing a SiC single crystal having a large growth thickness of 10 mm or greater by a solution process is provided. This is achieved by a method for producing a SiC single crystal, wherein a SiC seed crystal substrate is contacted with a Si—C solution with a temperature gradient, in which the temperature decreases from the interior toward the surface, to grow a SiC single crystal, and wherein the temperature gradient in the surface region of the Si—C solution is increased at least once while the SiC single crystal is grown with the (000-1) face as the growth surface, to grow a SiC single crystal having a growth thickness of 10 mm or greater.

### TECHNICAL FIELD

The present invention relates to a method for producing a SiC single crystal that is suitable for a semiconductor element, and more specifically it relates to a method for producing a SiC single crystal with a large thickness.

### BACKGROUND ART

SiC single crystals are thermally and chemically very stable, superior in mechanical strengths, and resistant to radiation, and also have superior physical properties, such as high breakdown voltage and high thermal conductivity compared to Si single crystals. They are therefore able to exhibit high output, high frequency, voltage resistance and environmental resistance that cannot be realized with existing semiconductor materials, such as Si single crystals and GaAs single crystals, and are considered ever more promising as next-generation semiconductor materials for a wide range of applications including power device materials that allow high power control and energy saving to be achieved, device materials for high-speed large volume information communication, high-temperature device materials for vehicles, radiation-resistant device materials and the like.

Typical growth processes for growing SiC single crystals that are known in the prior art include gas phase processes, the Acheson process and solution processes. Among gas phase processes, for example, sublimation processes have a drawback in that grown single crystals have been prone to hollow penetrating defects known as “micropipe defects”, lattice defects, such as stacking faults, and generation of polymorphic crystals. However, most SiC bulk single crystals are conventionally produced by sublimation processes because of the high crystal growth rate. In the Acheson process, heating is carried out in an electric furnace using silica stone and coke as starting materials, and therefore it has not been possible to obtain single crystals with high crystallinity due to impurities in the starting materials.

Solution processes are processes in which molten Si or an alloy melted in molten Si is situated in a graphite crucible and C is dissolved into the molten liquid, and a SiC crystal layer is deposited and grown on a seed crystal substrate set in the low temperature section. Solution processes can be expected to reduce defects since crystal growth is carried out in a state of near thermal equilibrium, compared to gas phase processes. In recent years, therefore, several methods for producing SiC single crystals by solution processes have been proposed, and for example, there has been proposed a method for producing a SiC single crystal with a flat growth surface at a high growth rate (PTL 1).

### CITATION LIST

### Patent Literature

[PTL 1] Japanese Unexamined Patent Publication No. 2008-303125

### SUMMARY OF THE INVENTION

### Problems to be Solved by the Invention

However, in the methods for producing SiC single crystals by solution processes that have been proposed in the prior art, it has been difficult to grow SiC single crystals having large thicknesses of 10 mm or greater.

### Means for Solving the Problems

The invention provides a method for producing a SiC single crystal, wherein a SiC seed crystal substrate is contacted with a Si—C solution with a temperature gradient, in which the temperature decreases from the interior toward the surface, to grow a SiC single crystal, and

wherein the temperature gradient in the surface region of the Si—C solution is increased at least once while the SiC single crystal is grown with the (000-1) face as the growth surface, to grow a SiC single crystal having a growth thickness of 10 mm or greater.

### Effect of the Invention

According to the invention, it is possible to obtain a SiC single crystal having a large growth thickness of 10 mm or greater by a solution process.

### BRIEF DESCRIPTION OF THE DRAWINGS

FIG. 1 is a graph showing the relationship between seed crystal substrate thickness and crystal growth rate, depending on a temperature gradient in the surface region of a Si—C solution, when SiC crystal growth was continued for 10 hours.

FIG. 2 is a schematic diagram showing the relationship between seed crystal thickness and temperature gradient in the surface region of a Si—C solution, according to the prior art.

FIG. 3 is a schematic diagram showing the relationship between seed crystal thickness and temperature gradient in the surface region of a Si—C solution, according to the invention.

FIG. 4 is a schematic diagram showing the relationship between crystal thickness and crystal growth rate, obtainable according to the invention.

FIG. 5 is a cross-sectional schematic drawing of an example of a single crystal production apparatus used in the invention.

FIG. 6 is a photograph of the outer appearance of a SiC single crystal grown in the example.

FIG. 7 is a photograph of the outer appearance of a SiC single crystal grown in the example.

FIG. 8 is a photograph of the outer appearance of a SiC single crystal grown in the example.

FIG. 9 is a photograph of the outer appearance of a SiC single crystal grown in the example.

FIG. 10 is a photograph of the outer appearance of a SiC single crystal grown in the example.

### DESCRIPTION OF EMBODIMENTS

Throughout the present specification, the indication “−1” in an expression, such as “(000-1) face”, is used where normally a transverse line is placed over the numeral.

It has been found that increasing the temperature gradient in the surface region of the Si—C solution by at least once while a SiC single crystal is grown with the (000-1) face as the growth surface is effective for obtaining a C-surface grown crystal with a large thickness.

The invention relates to a method for producing a SiC single crystal, wherein a SiC seed crystal substrate is contacted with a Si—C solution with a temperature gradient, in which the temperature decreases from the interior toward the surface, to grow a SiC single crystal, and wherein the temperature gradient in the surface region of the Si—C solution is increased at least once while the SiC single crystal is grown with the (000-1) face as the growth surface, to grow a SiC single crystal having a growth thickness of 10 mm or greater.

A solution process is used in the method for producing a SiC single crystal according to the invention. A solution process for production of a SiC single crystal is a method wherein the surface region of the Si—C solution becomes supersaturated due to formation of a temperature gradient in which the temperature decreases from the interior of the Si—C solution toward the surface of the solution in a crucible, and a SiC single crystal is grown on a seed crystal contacting with the Si—C solution.

In the method according to the invention, a SiC single crystal having quality commonly used for production of SiC single crystals may be used as the seed crystal. For example, a SiC single crystal commonly formed by using a sublimation process may be used as the seed crystal. A SiC single crystal commonly formed by such a sublimation process generally contains numerous threading dislocations.

In the method according to the invention, a SiC seed crystal with a (000-1) face is used to perform (000-1) face growth of a SiC single crystal by using a solution process with the (000-1) face of the seed crystal as the origin.

According to the present method, it is possible to obtain a SiC single crystal having a growth thickness of 10 mm or greater.

In order to obtain a C-surface grown crystal with a large thickness, there are methods in which the growth rate is increased or the growth time is lengthened. However, if the growth rate is too high in C-surface growth, macrodefects may be generated in the grown crystal, while if the growth time is long, a very long time may be required for crystal growth, or crystal growth may not occur beyond the prescribed thickness. Throughout the present specification, “macrodefects” in a SiC crystal refer to inclusions in the Si—C solution, crystals with different orientations (polycrystals), or combinations thereof.

Methods for obtaining C-surface grown crystals with large thicknesses also include repeating growth several times. Even when growth is repeated several times, however, a very long time is necessary when conducting crystal growth to a thickness of 10 mm or greater, or in some cases, it has not been possible to perform crystal growth to greater than certain thicknesses.

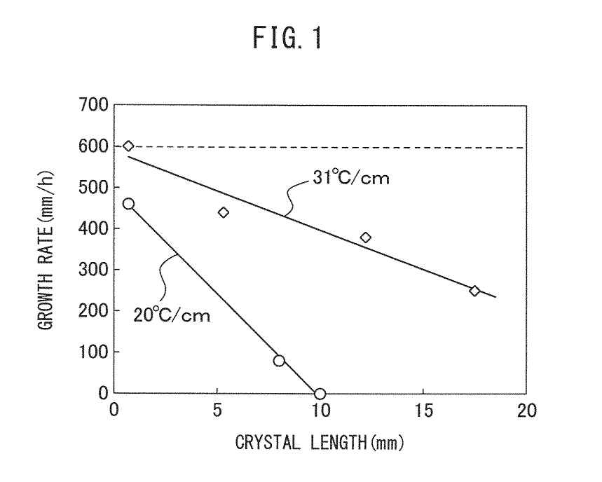

FIG. 1 shows the relationship between crystal thickness and crystal growth rate, depending on a temperature gradient in the surface region of a Si—C solution, when SiC crystal growth was continued for 10 hours on the (000-1) face (C-surface). In FIG. 1, the temperature gradient in the surface region of the Si—C solution is the average value of the temperature gradient in a range of 3 mm from the surface of the Si—C solution, the crystal thickness is the thickness of the SiC single crystal used as the seed crystal before initiating growth, and the crystal growth rate is the average crystal growth rate, which is the value of the thickness of the crystal grown for 10 hours divided by 10 hours. From FIG. 1, it is seen that a larger crystal thickness results in a lower crystal growth rate. Also, it is seen that increasing the temperature gradient in the surface region of the Si—C solution can increase the crystal growth rate.

While not being constrained by theory, it is believed that the reason that a long time is required during crystal growth, or that crystal growth does not occur beyond a certain thickness, is that since the SiC single crystal has higher thermal conductivity than the graphite shaft, a greater crystal growth thickness results in a smaller temperature gradient in the interface region between the SiC crystal growth surface and the Si—C solution, and thus a slower crystal growth rate.

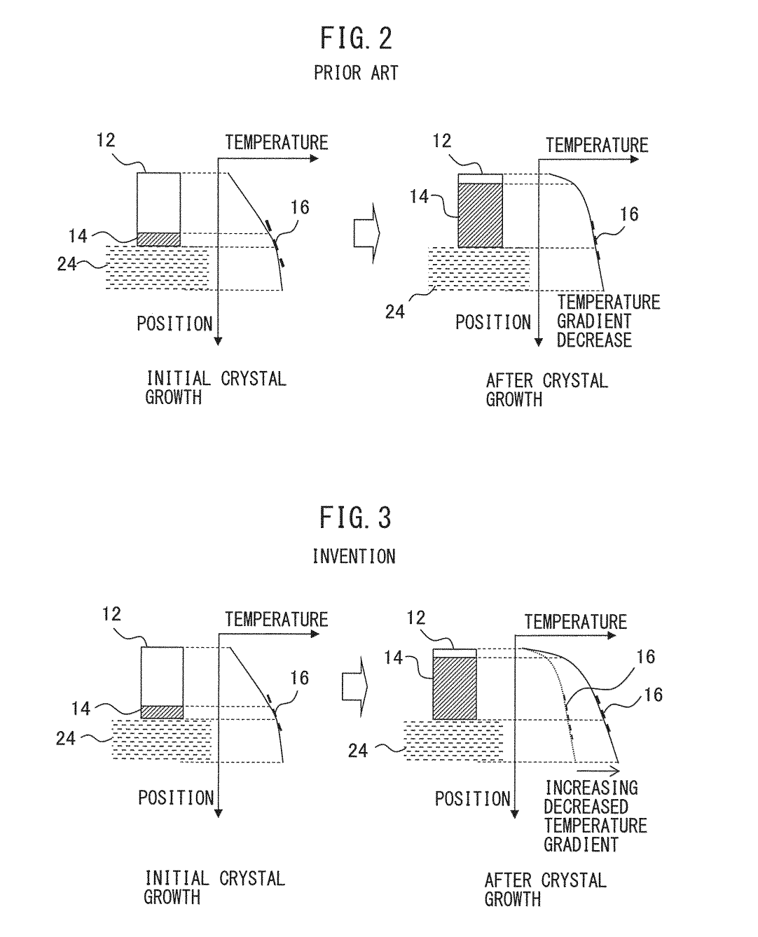

FIG. 2 is a schematic diagram showing the relationship between the thickness of a seed crystal 14 and the temperature gradient 16 in the surface region of a Si—C solution 24, according to the prior art. Presumably, the temperature gradient 16 is large at the initial crystal growth where the thickness of the seed crystal 14 is small, but after crystal growth has progressed the temperature gradient 16 is reduced.

This tendency has been found with C-surface growth, and increasing the temperature gradient in the surface region of the Si—C solution at least once during C-surface growth has been found to be effective for obtaining a C-surface grown crystal having a large growth thickness. By this method, it is possible to satisfactorily obtain a C-surface grown crystal with a thickness of 10 mm or greater, preferably 13 mm or greater, more preferably 16 mm or greater and even more preferably 20 mm or greater.

FIG. 3 is a schematic diagram showing the relationship between the thickness of a seed crystal 14 and the temperature gradient 16 in the surface region of a Si—C solution 24, according to the invention. According to the invention, it is possible to increase the temperature gradient 16 even after crystal growth has proceeded.

In the method according to the invention, preferably, the crystal growth rate set at first is not exceeded when the temperature gradient in the surface region of the Si—C solution is increased. This is because the temperature gradient in the surface region of the Si—C solution is generally set so that the highest growth rate is achieved within a range that does not generate macrodefects during initial crystal growth.

In the method according to the invention, crystal growth is preferably carried out in a manner that does not create macrodefects. In order to prevent generation of macrodefects, it is effective to perform crystal growth at below a prescribed growth rate, and when crystal growth is performed continuously for 10 hours, it is preferred for the crystal growth to be at an average growth rate of less than 600 μm/h, and it is more preferred for the crystal growth to be at an average growth rate of no greater than 460 μm/h.

In the method according to the invention, when crystal growth is perform continuously for 10 hours, the lower limit for the average growth rate of the SiC crystal is greater than 0 μm/h, preferably 100 μm/h or greater, more preferably 200 μm/h or greater, even more preferably 300 μm/h or greater and even more preferably 400 μm/h or greater.

In the method according to the invention, it is preferred to increase the temperature gradient at the surface region of the Si—C solution before the growth thickness of the SiC single crystal reaches 10 mm. This is because when crystal growth is performed continuously and the growth thickness of the SiC single crystal reaches about 10 mm, the growth rate may become approximately zero, as shown in FIG. 1.

The temperature gradient in the surface region of the Si—C solution may be increased, preferably before the SiC single crystal growth thickness reaches 8 mm, more preferably before it reaches 6 mm and even more preferably before it reaches 4 mm. For example, the temperature gradient may be increased before the growth thickness reaches 4 mm, and then the temperature gradient may be increased before the growth thickness reaches another 4 mm.

When it is not possible to monitor the growth thickness during SiC crystal growth, the relationship between the crystal thickness and crystal growth rate based on the temperature gradient in the surface region of the Si—C solution may be determined beforehand, as shown in FIG. 1, and the temperature gradient in the surface region of the Si—C solution may be increased in such a manner that the crystal growth rate is at the prescribed level at a timing at which the prescribed crystal thickness is reached.

When the relationship shown in FIG. 1 is obtained, and for example, if a seed crystal with a 0.7 mm thickness is prepared and crystal growth is performed for 10 hours at an average growth rate of 460 μm/h with the average temperature gradient in a depth range of 3 mm from the surface of the Si—C solution being 20° C./cm, crystal growth of 4.6 mm takes place, and therefore a crystal thickness of 5.3 mm is obtained. When growth is continued under these conditions for another 10 hours, an average growth rate of only 220 μm/h is obtained, and a total crystal thickness of only 7.5 mm is obtained by crystal growth of 2.2 mm. However, if the average temperature gradient is increased to 31° C./cm in a depth range of 3 mm from the surface of the Si—C solution when a crystal thickness of 5.3 mm is obtained, and growth is continued for another 10 hours, it is possible to perform growth at an average growth rate of 440 μm/h and achieve crystal growth of 4.4 mm, to obtain a total crystal thickness of 9.7 mm. When the average temperature gradient is 20° C./cm in a depth range of 3 mm from the surface of the Si—C solution, growth substantially ceases when the crystal thickness reaches about 10 mm, and therefore increasing the temperature gradient is effective for crystal growth.

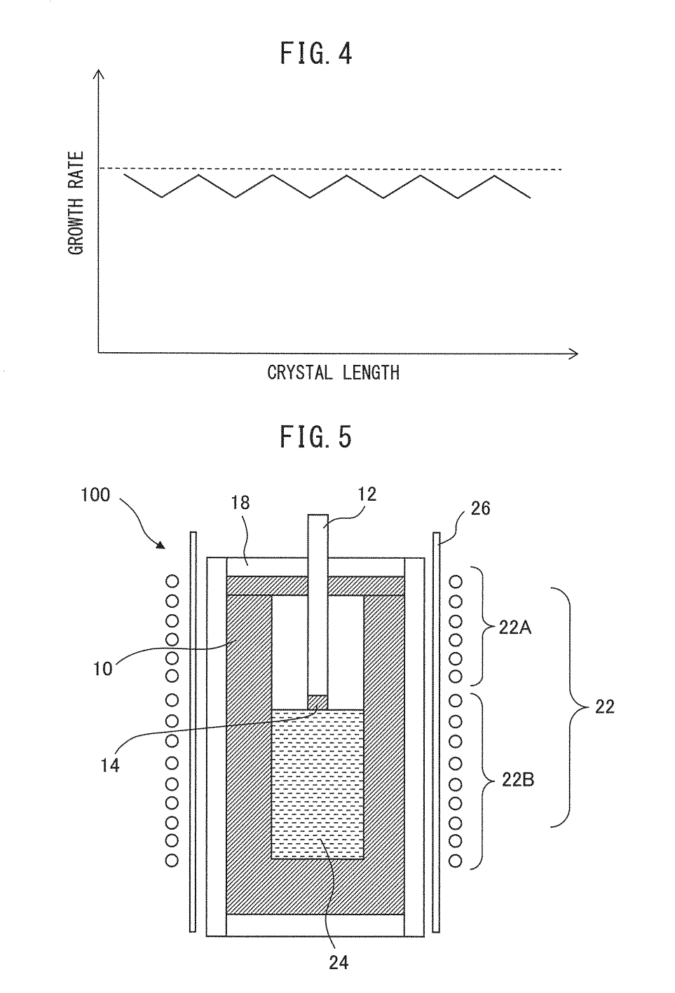

Crystal growth may be performed, for example, by recording more precise data beforehand and setting the program of crystal length (or growth time) and temperature gradient so that a substantially constant crystal growth rate can be obtained in the range up to the upper limit of the growth rate represented by the dashed line in the schematic view of FIG. 4.

In the method according to the invention, increasing the temperature gradient in the surface region of the Si—C solution during SiC crystal growth may thus be carried out at least one or more times.

When it is possible to monitor the growth thickness during SiC crystal growth, the crystal growth time may be measured to calculate the crystal growth rate. Feedback may be used to set the temperature gradient in the surface region of the Si—C solution, so as to obtain a prescribed crystal growth rate when the growth rate has fallen. For example, the crystal growth rate may be measured in brief intervals of 1 hour or less or in real time to increase the temperature gradient in the surface region of the Si—C solution so as to maintain a substantially constant growth rate regardless of the crystal growth thickness. This allows crystal growth, such as represented in FIG. 4, or crystal growth with a more constant growth rate to be more easily performed. When it is possible to measure the crystal growth rate in brief intervals of 1 hour or less or in real time, the upper limit for the growth rate is preferably no greater than 1500 μm/h.

The growth rate of the SiC single crystal can be adjusted by controlling the degree of supersaturation of the Si—C solution. If the degree of supersaturation of the Si—C solution is increased, the SiC single crystal growth rate increases, and if the degree of supersaturation is decreased, the SiC single crystal growth rate decreases.

The degree of supersaturation of the Si—C solution can be controlled primarily by the surface temperature of the Si—C solution and the temperature gradient in the surface region of the Si—C solution, and for example, the degree of supersaturation can be lowered by decreasing the temperature gradient in the surface region of the Si—C solution while maintaining a constant surface temperature of the Si—C solution, or the degree of supersaturation can be raised by increasing the temperature gradient in the surface region of the Si—C solution while maintaining a constant surface temperature of the Si—C solution.

It is possible to form the prescribed temperature gradient in the direction perpendicular to the surface of the Si—C solution by adjusting the placement, configuration, and power of the heating device, such as a high-frequency coil situated around the crucible of the single crystal production apparatus. The method of controlling the temperature gradient in the surface region of the Si—C solution will be described in more detail below with reference to the accompanying drawings.

Alternatively, the seed crystal holding shaft may be cooled to increase the temperature gradient in the surface region of the Si—C solution. The method of cooling the seed crystal holding shaft may be, for example, blowing gas or pouring cooling water onto the seed crystal holding shaft, or bringing a low temperature member close to the seed crystal holding shaft. The temperature gradient in the surface region of the Si—C solution may also be increased by cooling the grown SiC single crystal. The method of cooling the grown SiC single crystal may be, for example, blowing gas onto or bringing a low temperature member close to at least a portion of the grown crystal.

The seed crystal to be used in the method according to the invention may have any desired shape, such as laminar, discoid, cylindrical, columnar, truncated circular conic or truncated pyramidal. The (000-1) face of the seed crystal may be used as the bottom face of the seed crystal contacting with the Si—C solution surface, and the top face on the opposite side may be used as the face held on the seed crystal holding shaft, such as a graphite shaft.

The (000-1) face of the seed crystal substrate to be used in the method according to the invention includes planes with offset angles of preferably within ±10°, more preferably within ±8°, even more preferably within ±4°, and yet more preferably it is the just surface.

Throughout the present specification, the temperature gradient in the surface region of the Si—C solution is the temperature gradient in the direction perpendicular to the surface of the Si—C solution, which is a temperature gradient where the temperature falls from the interior of the Si—C solution toward the surface of the solution. The temperature gradient can be calculated as the average value obtained by pre-measuring the temperature A on the surface of the Si—C solution which is the low-temperature side, and temperature B which is the high-temperature side at a prescribed depth from the surface of the Si—C solution to the solution side in the direction perpendicular to the surface of the Si—C solution, by using a thermocouple before contacting the seed crystal substrate with the Si—C solution, and dividing the temperature difference by the distance between the positions at which temperature A and temperature B were measured. For example, when measuring the temperature gradient between the surface of the Si—C solution and the position at depth D cm from the surface of the Si—C solution to the solution side in the direction perpendicular to the surface of the Si—C solution, the temperature gradient can be calculated by the following formula:

temperature gradient (° C./cm)=(B−A)/D

wherein the temperature gradient is the difference between the surface temperature A of the Si—C solution and the temperature B at a position at depth D cm from the surface of the Si—C solution to the solution side in the direction perpendicular to the surface of the Si—C solution, divided by D cm.

The range of control of the temperature gradient is preferably from the surface of the Si—C solution to a depth of 3 mm. In that case, the temperature gradient (° C./cm) in the formula is the value obtained when the difference between the surface temperature A of the Si—C solution and the temperature B at a position at a depth of 3 cm from the surface of the Si—C solution to the solution side in the direction perpendicular to the surface of the Si—C solution, is divided by 3 cm.

When the range of control of the temperature gradient is too shallow, the range in which the temperature gradient is controlled will be shallow and the range in which the degree of supersaturation of C is controlled will also be shallow, sometimes causing growth of the SiC single crystal to be unstable. If the range of control of the temperature gradient is too deep, the range in which the degree of supersaturation of C is controlled will also be deep, which is effective for stable growth of the SiC single crystal, but in actuality the depth contributing to single crystal growth is very close to the surface of the Si—C solution and it is sufficient to control the temperature gradient up to a depth of several mm from the surface. Consequently, in order to perform stable SiC single crystal growth and temperature gradient control, it is preferred to control the temperature gradient within the depth range specified above.

The presence of macrodefects in the SiC crystal can be observed using a microscope. If the grown SiC crystal is sliced to a thickness of about 1 to 3 mm and observed with light directed from below, the SiC single crystal portion appears transparent while sections containing inclusions appear black, and sections with crystals having different orientations (polycrystalline sections) can be easily distinguished as not being a single crystalline structure, so that the presence of macrodefects can be easily discerned. The outer appearance of the grown crystal may simply be observed when presence of macrodefects is easily discernible.

Placement of the seed crystal substrate in the single crystal production apparatus may be done by holding the top face of the seed crystal substrate on the seed crystal holding shaft as described above. A carbon adhesive may be used for holding the seed crystal substrate on the seed crystal holding shaft.

Contact of the seed crystal substrate with the Si—C solution may be performed by lowering the seed crystal holding shaft holding the seed crystal substrate toward the Si—C solution surface, and contacting it with the Si—C solution while the bottom face of the seed crystal substrate is parallel to the Si—C solution surface. The seed crystal substrate may be held at a prescribed position relative to the Si—C solution surface for growth of the SiC single crystal.

The holding position of the seed crystal substrate may be such that the position of the bottom face of the seed crystal substrate matches the Si—C solution surface, is below the Si—C solution surface, or is above the Si—C solution surface. When it is held so that the bottom face of the seed crystal substrate is at a position above the Si—C solution surface, the seed crystal substrate is contacted once with the Si—C solution so that the Si—C solution contacts with the bottom face of the seed crystal substrate, and it is then raised to the prescribed position. The position of the bottom face of the seed crystal substrate may match the Si—C solution surface or be lower than the Si—C solution surface, but it is preferable that the Si—C solution does not contact with the seed crystal holding shaft in order to prevent generation of polycrystals. In such methods, the position of the seed crystal substrate may be adjusted during growth of the single crystal.

The seed crystal holding shaft may be a graphite shaft holding the seed crystal substrate at one end face. The seed crystal holding shaft may have any desired shape, such as cylindrical or columnar, and there may be used a graphite shaft having the same end face shape as the top face of the seed crystal substrate.

According to the invention, a Si—C solution is a solution in which C is dissolved where the solvent is a molten liquid of Si or Si/X (X is one or more metals other than Si). X is not particularly restricted so long as it is one or more metals and can form a liquid phase (solution) that is in a state of thermodynamic equilibrium with SiC (solid phase). Suitable examples of X metals include Ti, Mn, Cr, Ni, Ce, Co, V and Fe. The Si—C solution preferably has a composition comprising Si and Cr.

The Si—C solution is more preferably a Si—C solution wherein the solvent is a molten liquid of Si/Cr/X (where X represents one or more metals other than Si and Cr). A Si—C solution wherein the solvent is a molten liquid with an atomic composition percentage of Si/Cr/X=30-80/20-60/0-10, has low variation in C dissolution and is therefore more preferred. For example, Cr, Ni and the like may be loaded into the crucible in addition to Si, to form a Si—Cr solution, Si—Cr—Ni solution or the like.

In the method according to the invention, the temperature of the Si—C solution is the surface temperature of the Si—C solution. The lower limit for the temperature of the surface of the Si—C solution is preferably 1800° C. or higher and the upper limit is preferably 2200° C., since the C dissolution in the Si—C solution can be increased within this temperature range. When an n-type SiC single crystal is to be grown, the lower limit for the temperature of the surface of the Si—C solution is preferably 2000° C. or higher from the viewpoint of allowing the amount of nitrogen dissolution in the Si—C solution to be increased.

Temperature measurement of the Si—C solution can be carried out by using a thermocouple or radiation thermometer. From the viewpoint of high temperature measurement and preventing inclusion of impurities, the thermocouple is preferably a thermocouple comprising tungsten-rhenium wire covered with zirconia or magnesia glass, placed inside a graphite protection tube.

FIG. 5 shows an example of a SiC single crystal production apparatus suitable for carrying out the method of the invention. The illustrated SiC single crystal production device 100 comprises a crucible 10, wherein the crucible 10 receives a Si—C solution 24 having C dissolved in a molten liquid of Si or Si/X, a temperature gradient is formed in which the temperature is decreased from the interior of the Si—C solution toward the surface of the solution, and the seed crystal substrate 14 that is held at the tip of the vertically movable graphite shaft 12 is contacted with the Si—C solution 24 to allow growth of the SiC single crystal. The crucible 10 and the graphite shaft 12 are preferably rotated.

The Si—C solution 24 is prepared by loading the starting materials into the crucible, melting them by heating to prepare Si or Si/X molten liquid, and dissolving C therein. If the crucible 10 is a carbonaceous crucible, such as a graphite crucible, or SiC crucible, C will dissolve into the molten liquid by dissolution of the crucible 10, thereby forming a Si—C solution. This will avoid the presence of undissolved C in the Si—C solution 24, and prevent waste of SiC by deposition of the SiC single crystal onto the undissolved C. The supply of C may be performed by utilizing a method of, for example, blowing in hydrocarbon gas or loading a solid C source together with the other molten liquid starting material, or these methods may be combined together with dissolution of the crucible.

For thermal insulation, the outer periphery of the crucible 10 is covered with a heat-insulating material 18. These are housed together inside a quartz tube 26. A high-frequency coil 22 for heating is disposed around the outer periphery of the quartz tube 26. The high-frequency coil 22 may be configured with an upper level coil 22A and a lower level coil 22B. The upper level coil 22A and lower level coil 22B can be independently regulated.

Since the temperatures of the crucible 10, the heat-insulating material 18, the quartz tube 26, and the high-frequency coil 22 become high, they are situated inside a water-cooling chamber. The water-cooling chamber is provided with a gas inlet and a gas exhaust vent to allow atmospheric modification in the apparatus to Ar, He or the like.

The temperature of the Si—C solution usually has a temperature distribution with a lower temperature at the surface of the Si—C solution than the interior thereof due to thermal radiation and the like. Further, a prescribed temperature gradient can be formed in the direction perpendicular to the surface of the Si—C solution 24 so that an upper portion of the solution in which the seed crystal substrate 14 is immersed is at low temperature and a lower portion of the solution is at high temperature, by adjusting number of coils and spacing of the high-frequency coil 22, a positional relationship of the high-frequency coil 22 and the crucible 10 in the height direction, and the output of the high-frequency coil 22. For example, the output of the upper level coil 22A may be smaller than the output of the lower level coil 22B, to form a prescribed temperature gradient in the Si—C solution 24 in which an upper portion of the solution is at low temperature and a lower portion of the solution is at high temperature.

The C dissolved in the Si—C solution 24 is dispersed by diffusion and convection. In the vicinity of the bottom surface of the seed crystal substrate 14, a temperature gradient is formed, in which the temperature is lower compared to a lower portion of the Si—C solution 24, by utilizing the power control of the upper level and lower level of the coil 22, heat radiation from the surface of the Si—C solution 24, and heat loss through the graphite shaft 12. When the C dissolved in the lower part of the solution where the temperature and the solubility are high, reaches the region near the bottom face of the seed crystal substrate where the temperature and the solubility are low, a supersaturation state appears and a SiC single crystal is grown on the seed crystal substrate by virtue of supersaturation as a driving force.

In some embodiments, meltback may be carried out in which the surface layer of the SiC seed crystal substrate is dissolved in the Si—C solution and removed prior to growth of a SiC single crystal. Since the surface layer of the seed crystal substrate on which the SiC single crystal is grown may have an affected layer, such as a dislocation, a natural oxide film, or the like, removal of the same by dissolution prior to growth of a SiC single crystal is effective for growing a high-quality SiC single crystal. Although the thickness of a layer to be removed depends on processed conditions of the surface of a SiC seed crystal substrate, it is preferably approximately 5 to 50 μm for sufficient removal of an affected layer and a natural oxide layer.

The meltback may be performed by forming a temperature gradient in which the temperature increases from the interior of the Si—C solution toward the surface of the solution, i.e., by forming, in the Si—C solution, a temperature gradient in a direction opposite to the case of SiC single crystal growth. The temperature gradient in the opposite direction can be formed by regulating the output of the high-frequency coil.

The meltback can also be performed, without forming a temperature gradient in the Si—C solution, by simply immersing the seed crystal substrate in the Si—C solution heated to a temperature higher than the liquidus temperature. In that case, the dissolution rate increases with higher Si—C solution temperature, but control of the amount of dissolution becomes difficult, while a low temperature may slow the dissolution rate.

In some embodiments, the seed crystal substrate may be preheated in advance, and then the same is contacted with the Si—C solution. If the seed crystal substrate at a low temperature is contacted with the Si—C solution at high temperature, heat shock dislocations may be generated in the seed crystal. Preheating of the seed crystal substrate before contacting the seed crystal substrate with the Si—C solution prevents heat shock dislocation and is effective for growth of a high-quality SiC single crystal. The seed crystal substrate may be heated together with the graphite shaft. Alternatively, the Si—C solution may be heated to the temperature for crystal growth after contacting the seed crystal substrate with the Si—C solution at a relatively low temperature. This is also effective for preventing heat shock dislocations and growing a high-quality SiC single crystal.

### EXAMPLES

### Example 1

There was prepared a SiC single crystal formed by a sublimation process, which was a discoid 4H—SiC single crystal with a diameter of 25 mm, a thickness of 0.7 mm, and the bottom face as the (000-1) face (just surface), for use as a seed crystal substrate. The top face of the seed crystal substrate was bonded to roughly the center section of the end face of a cylindrical graphite shaft, using a graphite adhesive.

A single crystal production apparatus as shown in FIG. 5 was used, and Si/Cr were loaded in as molten liquid materials at an atomic composition percentage of 60:40, in a graphite crucible for accommodating a Si—C solution 24. The air in the single crystal production apparatus was exchanged with helium. A high-frequency coil 22 situated around the periphery of the graphite crucible 10 was electrified to melt the starting material in the graphite crucible 10 by heating, thereby forming a Si/Cr alloy molten liquid. Then, a sufficient amount of C was dissolved into the Si/Cr alloy molten liquid from the graphite crucible 10 to form a Si—C solution 24.

The outputs of the upper level coil 22A and lower level coil 22B were adjusted to heat the graphite crucible 10, forming a temperature gradient in which the temperature was decreased from the interior of the Si—C solution 24 toward the surface of the solution. Formation of the prescribed temperature gradient was confirmed by using a vertically movable thermocouple to measure the temperature of the Si—C solution 24. Outputs of the high-frequency coils 22A and 22B were adjusted so that the temperature of the surface of the Si—C solution 24 is increased to 2000° C., and the temperature gradient, in which the temperature falls from the solution interior in a range of 3 mm from the solution surface toward the solution surface, is 20° C./cm.

Seed touching was performed, in which the position of the bottom face of the seed crystal substrate was placed at a position matching the liquid surface of the Si—C solution, and the bottom face of the seed crystal substrate was contacted with the Si—C solution, while keeping the bottom face (C-surface) of the seed crystal substrate bonded to the graphite shaft in parallel to the Si—C solution surface. The graphite shaft was then pulled upward so that the position of the bottom face of the seed crystal substrate was 1.5 mm above the liquid surface of the Si—C solution. A SiC crystal was grown for 10 hours while maintaining the position of the bottom face of the seed crystal substrate at a 1.5 mm raised position.

After 10 hours of crystal growth, the graphite shaft was raised, and the seed crystal substrate and the SiC crystal grown from the seed crystal substrate were severed from the Si—C solution and graphite shaft and was recovered. The obtained grown crystal was a single crystal, and had a growth thickness of 4.6 mm. The total thickness of the seed crystal substrate and grown crystal was 5.3 mm. The diameter of the grown crystal is the diameter of the smallest circle that encloses the growth surface, and the thickness of the grown crystal is the thickness of the grown crystal at the center section of the growth surface (same hereunder). The average growth rate was 460 μm/h.

### Example 2

(000-1) face growth was performed under the same conditions as in Example 1, except that the 5.3 mm-thick SiC crystal grown in Example 1 was used directly as a seed crystal without polishing, and the growth time was 15 hours.

The obtained grown crystal was a single crystal, and had a growth thickness of 2.7 mm. The total thickness of the seed crystal and grown crystal was 8.0 mm. The average growth rate was 180 μm/h.

### Example 3

The 8.0 mm-thick SiC crystal grown in Example 2 was used directly as a seed crystal without polishing, to perform (000-1) face growth under the same conditions as in Example 1.

The obtained grown crystal was a single crystal, and had a growth thickness of 0.8 mm. The total thickness of the seed crystal and grown crystal was 8.8 mm. The average growth rate was 80 μm/h.

### Example 4

(000-1) face growth was performed under the same conditions as in Example 1, except that the 8.8 mm-thick SiC crystal grown in Example 3 was used directly as a seed crystal without polishing, and the growth time was 40 hours.

The obtained grown crystal was a single crystal, and had a growth thickness of 1.2 mm. The total thickness of the seed crystal and grown crystal was 10.0 mm. The average growth rate was 30 μm/h.

### Example 5

The 10.0 mm-thick SiC crystal grown in Example 4 was used directly as a seed crystal without polishing, to perform (000-1) face growth under the same conditions as in Example 1.

When the thickness of the grown crystal section was measured, the growth thickness was found to be 0.0 mm. That is, the total thickness of the seed crystal and grown crystal was 10.0 mm, and there was no change from the seed crystal thickness.

### Example 6

(000-1) face growth was performed under the same conditions as in Example 1, except that a 5.3 mm-thick SiC crystal grown under the same conditions as in Example 1 was used directly as a seed crystal without polishing, and the temperature gradient was 31° C./cm.

The obtained grown crystal was a single crystal, and had a growth thickness of 4.4 mm. The total thickness of the seed crystal substrate and grown crystal were 9.7 mm. The growth rate was 440 μm/h.

### Example 7

(000-1) face growth was performed under the same conditions as in Example 1, except that the 9.7 mm-thick SiC crystal grown in Example 6 was used directly as a seed crystal without polishing, the temperature gradient was 31° C./cm, and the growth time was 6 hours.

The obtained grown crystal was a single crystal, and had a growth thickness of 2.5 mm. The total thickness of the seed crystal substrate and grown crystal was 12.2 mm. The growth rate was 417 μm/h.

### Example 8

(000-1) face growth was performed under the same conditions as in Example 1, except that the 12.2 mm-thick SiC crystal obtained in Example 7 was used directly as a seed crystal without polishing, and the temperature gradient was 31° C./cm.

The obtained grown crystal was a single crystal, and had a growth thickness of 3.8 mm. The total thickness of the seed crystal substrate and grown crystal was 16.0 mm. The growth rate was 380 μm/h.

### Example 9

(000-1) face growth was performed under the same conditions as in Example 1, except that the 16.0 mm-thick SiC crystal obtained in Example 8 was used directly as a seed crystal without polishing, the temperature gradient was 31° C./cm, and the growth time was 5 hours.

The obtained grown crystal was a single crystal, and had a growth thickness of 1.5 mm. The total thickness of the seed crystal substrate and grown crystal was 17.5 mm. The growth rate was 300 μm/h.

### Example 10

(000-1) face growth was performed under the same conditions as in Example 1, except that the 17.5 mm-thick SiC crystal obtained in Example 9 was used directly as a seed crystal without polishing, and the temperature gradient was 31° C./cm.

The obtained grown crystal was a single crystal, and had a growth thickness of 2.5 mm. The total thickness of the seed crystal substrate and grown crystal was 20.0 mm. The growth rate was 250 μm/h.

### Example 11

There was prepared a SiC single crystal formed by a sublimation process, which was a discoid 4H—SiC single crystal with a diameter of 25 mm, a thickness of 0.7 mm, and the bottom face as the (000-1) face (only surface), for use as a seed crystal substrate. The (000-1) face growth was performed under the same conditions as in Example 1, except that the temperature gradient was 31° C./cm.

The obtained grown crystal was a single crystal, and had a growth thickness of 6.0 mm. The total thickness of the seed crystal substrate and grown crystal was 6.7 mm. The growth rate was 600 μm/h.

FIG. 1 shows the relationship between seed crystal thickness and crystal growth rate for 10 hours of growth in Examples 1, 3, 5, 6, 8, 10 and 11.

It has been found that during C-surface growth, increasing the crystal thickness produced a tendency toward a lower crystal growth rate, but a higher temperature gradient in the surface region of the Si—C solution allowed the growth rate to be increased.

### (Observing Presence of Macrodefects)

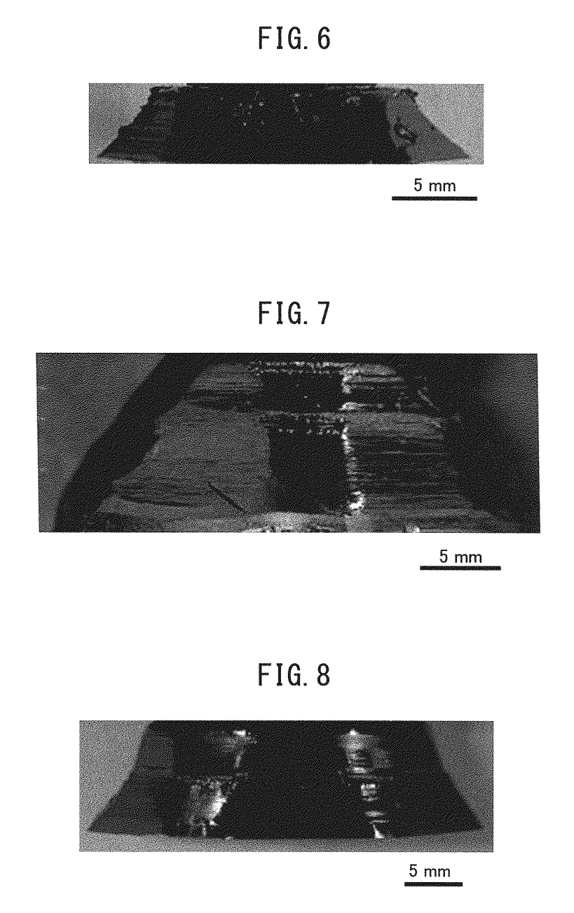

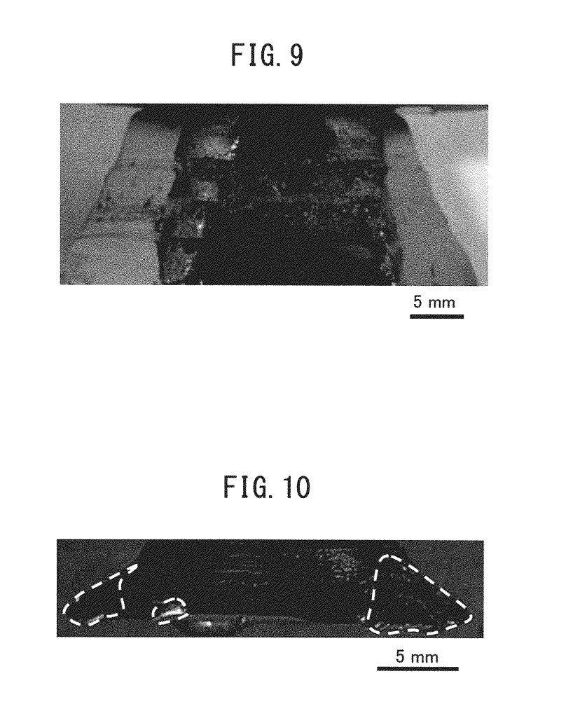

The presence of macrodefects in the SiC single crystals grown in the examples was evaluated. FIGS. 6 to 10 are photographs showing the outer appearance of the SiC single crystals grown in Examples 1, 5, 6, 10 and 11. No macrodefects were seen in the SiC crystals grown in Examples 1, 5, 6 and 10. No macrodefects were also seen in the SiC crystals grown in Examples 2 to 4 and 7 to 9. The SiC crystal grown in Example 11 had crude crystals in the sections surrounded by dashed lines.

Table 1 summarizes the growth conditions for Examples 1 to 11, and the grown crystal thicknesses, growth rates, and presence of macrodefects.

TABLE 1
Growth conditions for Examples 1 to 11, and
grown crystal thicknesses, growth rates, and macrodefects

| | Seed | | | | | |
|---|---|---|---|---|---|---|
| | crystal | Temp- | | Growth | | Presence |
| | thick- | erature | Growth | thick- | Growth | of |
| | ness | gradient | time | ness | rate | macro- |
| | (mm) | (° C./cm) | (h) | (mm) | (μm/h) | defects |
| Example 1 | 0.7 | 20 | 10 | 4.6 | 460 | Absent |
| Example 2 | 5.3 | 20 | 15 | 2.7 | 180 | Absent |
| Example 3 | 8.0 | 20 | 10 | 0.8 | 80 | Absent |
| Example 4 | 8.8 | 20 | 40 | 1.2 | 30 | Absent |
| Example 5 | 10.0 | 20 | 10 | 0.0 | 0 | Absent |
| Example 6 | 5.3 | 31 | 10 | 4.4 | 440 | Absent |
| Example 7 | 9.7 | 31 | 6 | 2.5 | 417 | Absent |
| Example 8 | 12.2 | 31 | 10 | 3.8 | 380 | Absent |
| Example 9 | 16.0 | 31 | 5 | 1.5 | 300 | Absent |
| Example 10 | 17.5 | 31 | 10 | 2.5 | 250 | Absent |
| Example 11 | 0.7 | 31 | 10 | 6.0 | 600 | Present |

### EXPLANATION OF SYMBOLS

10 Graphite crucible
12 Graphite shaft
14 Seed crystal substrate
16 Temperature gradient in surface region of Si—C solution
18 Heat-insulating material
22 High-frequency coil
22A Upper level high-frequency coil
22B Lower level high-frequency coil
24 Si—C solution
26 Quartz tube
100 Single crystal production apparatus

What is claimed is:

1. A method for producing a SiC single crystal, wherein a SiC seed crystal substrate is contacted with a Si—C solution with a temperature gradient, in which the temperature decreases from the interior toward the surface, to grow a SiC single crystal, and
wherein the temperature gradient in the surface region of the Si—C solution is increased at least once while the SiC single crystal is grown with the (000-1) face as the growth surface, to grow a SiC single crystal having a growth thickness of 10 mm or greater.

2. The method for producing a SiC single crystal according to claim 1, wherein the temperature gradient in the surface region of the Si—C solution is increased before the growth thickness of the SiC single crystal reaches 10 mm.

3. The method for producing a SiC single crystal according to claim 1, wherein the average growth rate during continuous growth of the SiC single crystal for 10 hours is greater than 0 μm/h and less than 600 μm/h.

4. The method for producing a SiC single crystal according to claim 2, wherein the average growth rate during continuous growth of the SiC single crystal for 10 hours is greater than 0 μm/h and less than 600 μm/h.
